(19) United States
(12) Patent Application Publication
(10) Pub. No.: US 2026/0190992 A1
(43) Pub. Date: Jul. 2, 2026

(54) BONDED STRUCTURE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Yoshihiko KANDA, Nisshin-shi (JP); Tomohito IWASHIGE, Nisshin-shi (JP)

(21) Appl. No.: 19/382,639

(22) Filed: Nov. 7, 2025

(30) Foreign Application Priority Data
Dec. 26, 2024 (JP) 2024-230647

(51) Int. Cl. H01L 23/00; H01L 23/373; H01L 23/495

(52) U.S. Cl. CPC H10W 40/257; H10W 70/461; H10W 72/322; H10W 72/324; H10W 72/352; H10W 90/736

(57) ABSTRACT

A bonded structure includes a first member, a second member, and a sinter-bonding layer. The second member includes a brush structure formed of multiple metal wires, each of which has a columnar shape. The sinter-bonding layer bonds the first member to the brush structure and is disposed apart from a portion of the second member that is different from the brush structure. The multiple metal wires extend in an extension direction. Porosity is defined as a proportion of an area occupied by gaps between the multiple metal wires in the brush structure in a plane perpendicular to the extension direction. The porosity of the brush structure falls within a range from 15% to 85%.

### CROSS REFFERENCE TO RELATED APPLICATION

This application is based on and incorporates herein by reference Japanese Patent Application No. 2024-230647 filed on Dec. 26, 2024.

### TECHNICAL FIELD

This disclosure relates to a bonded structure using metal wires and a sintered material.

### BACKGROUND

Conventionally, a bonded structure, in which two members are sinter-bonded using metal nanoparticles having high thermal conductivity, is known.

### SUMMARY

According to at least one embodiment of the present disclosure, a bonded structure includes a first member, a second member, and a sinter-bonding layer. The second member may include a brush structure formed of multiple metal wires, each of which has a columnar shape. The sinter-bonding layer may bond the first member to the brush structure and may be disposed apart from a portion of the second member that is different from the brush structure. The multiple metal wires may extend in an extension direction. Porosity is defined as a proportion of an area occupied by gaps between the multiple metal wires in the brush structure in a plane perpendicular to the extension direction. The porosity of the brush structure may fall within a range from 15% to 85%.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a cross-sectional view of a bonded structure according to an embodiment.

FIG. 2 is an explanatory diagram of a bonding step for the bonded structure in FIG. 1.

FIG. 3 is a cross-sectional view taken along line III-III in FIG. 2, and is an explanatory diagram illustrating porosity of a brush structure.

FIG. 4 is an explanatory diagram illustrating reduction of void generation in the bonded structure according to the embodiment.

FIG. 5 is an explanatory diagram of a bonded structure and void generation in a comparative example.

FIG. 6 is a scanning electron microscope (SEM) image showing a semiconductor element with a brush structure formed.

FIG. 7A is a table showing evaluation results regarding bonded structures according to working examples.

FIG. 7B is a table showing evaluation results regarding bonded structures according to working examples and comparative examples.

### DESCRIPTION OF EMBODIMENTS

To begin with, examples of relevant techniques will be described.

There is a bonded structure, in which two members are sinter-bonded using metal nanoparticles having high thermal conductivity. Sinter-bonding materials containing metal nanoparticles often have organic substances or moisture on surfaces of the metal nanoparticles, and these substances may be released as gases during a sinter-bonding process. If the gases generated during the sinter-bonding process remain in a bonding portion, voids, i.e., empty spaces, are formed, thereby decreasing bonding strength and reliability of the bonded structure. In particular, the large bonding area is likely to cause the voids to generate at a center of the bonding portion. Furthermore, when sinter-bonding is performed under pressure, this application of pressure may cause members for bonding to crack, or reduce productivity. Thus, bonding without pressure has been attracting attention in recent years.

The bonded structure described above is manufactured by sinter-bonding without pressure, using a sinter-bonding material containing metal nanoparticles. The bonded structure is manufactured by applying a paste of sinter-bonding material to a first member, placing a second member on the paste, and then carrying out a volatilization step to evaporate volatile components contained in the paste, followed by a sintering step in which these members are bonded together by heating without pressure.

The bonded structure uses a sinter-bonding material containing metal nanoparticles, and is bonded without pressure even when a bonding area is large, and undergoes a volatilization step, thereby reducing generation of voids. However, the bonded structure is sinter-bonded through two steps that are the above-mentioned volatilization step and the subsequent sintering step by heating, which leaves room for improvement in terms of productivity.

The present disclosure has been made in view of the above circumstances. According to the present disclosure, a bonded structure uses a sinter-bonding material containing metal nanoparticles and is capable of being bonded without pressure even when a bonding area is large, while achieving both reduction of void generation and improvement of productivity.

According to one aspect of the present disclosure, a bonded structure includes a first member, a second member, and a sinter-bonding layer. The second member includes a brush structure formed of multiple metal wires each of which extends in a columnar shape in an extension direction. The sinter-bonding layer bonds the first member to the brush structure, and is disposed apart from a portion of the second member that is different from the brush structure. Porosity is defined as a proportion of an area occupied by gaps between the multiple metal wires in the brush structure, in a plane perpendicular to the extension direction. The porosity of the brush structure falls within a range from 15% to 85%.

The bonded structure includes the first member and the second member that includes the brush structure. The sinter-bonding layer, which is disposed apart from a portion of the second member that is different from the brush structure, is bonded to the brush structure. The brush structure is formed of the columnar multiple metal wires. The porosity of the brush structure, which is defined as a proportion of an area occupied by gaps between the multiple metal wires in the plane perpendicular to the extension direction, is between 15%, inclusive and 85%, inclusive. Since the bonded structure includes a structure in which the brush structure having the porosity in the range from 15% to 85% is disposed on the sinter-bonding layer, a gas generated from a material of the sinter-bonding layer during a sintering step can flow out of empty spaces in the brush structure. Thus, the bonded structure does not need a volatilization step that allows the gas generated from the material of the sinter-bonding layer to flow out of the bonded structure even when a large bonding area is sintered without pressure. Thus, the bonded structure can achieve both improved productivity and reduction of void generation.

Hereinafter, embodiments of the present disclosure will be described with reference to the drawings. In each of the following embodiments, parts that are identical or equivalent to each other are denoted with the same reference numerals, and a description of the same or equivalent portions may be omitted. When only some of the configuration elements are described in the embodiment, the remaining configuration elements can be referred from those described in the preceding embodiment. The following embodiments may be partially combined with each other even if such a combination is not explicitly described as long as there is no disadvantage with respect to such a combination.

### Embodiment

A bonded structure 1 according to an embodiment will be described.

### Basic Configuration

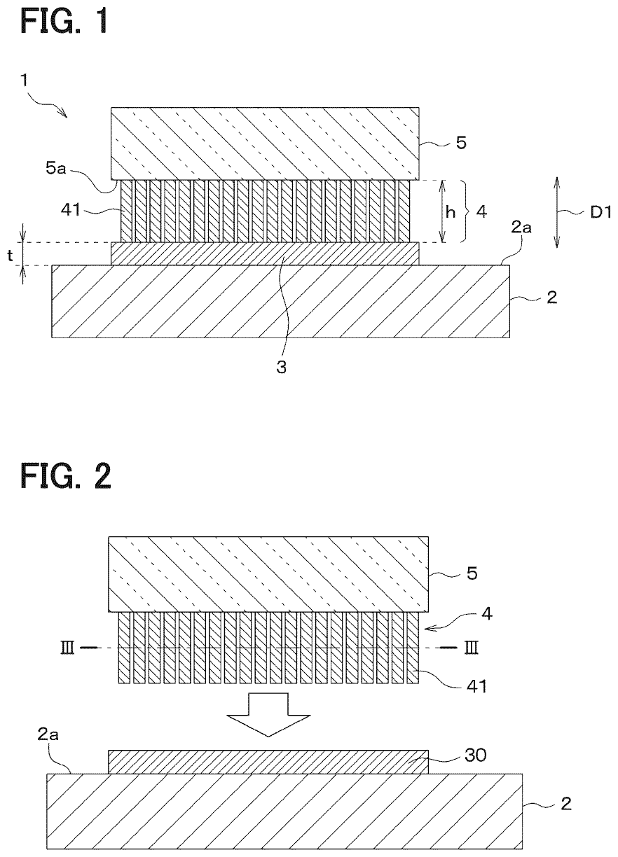

As shown in FIG. 1, the bonded structure 1 has a structure in which a heat spreader 2 as a first member and a semiconductor element 5 as a second member are joined via a sinter-bonding layer 3 and a brush structure 4. The bonded structure 1 constitutes a semiconductor device in which the semiconductor element 5 is a power semiconductor and a heat-dissipating path is provided. The heat-dissipating path releases a heat generated during operation of the semiconductor element 5 to the heat spreader 2 via the brush structure 4 and the sinter-bonding layer 3.

For, example, the heat spreader 2 is a part of a lead frame made of a conductive material such as copper (Cu), iron (Fe), or a metal alloy thereof, and is formed by press-stamping. The heat spreader 2 is a heat-dissipating member that releases the heat generated by the semiconductor element 5 during operation to an outside of the semiconductor element 5. The heat spreader 2 includes one surface 2a that is joined to the brush structure 4 formed on the semiconductor element 5, via the sinter-bonding layer 3. The term “heat spreader” as used here is defined as a member capable of efficiently releasing heat, and may be not only the above-described lead frame, but an insulating heat-dissipating substrate having metal layers such as copper formed on both surfaces of a ceramic substrate. Other known heat-dissipating members may also be used.

For example, the sinter-bonding layer 3 may be formed by heating a sinter-bonding material containing metal nanoparticles to a temperature at or below the melting point thereof to sinter the sinter-bonding material. As the metal nanoparticles, copper, silver (Ag), or other metallic materials having higher thermal conductivity than that of solder, or combinations thereof, may be used. Higher thermal conductivity than that of solder means, for example, to be higher than that of typical lead-rich solder (Pb—5Sn), which is 35 W/mK. Other metal nanoparticles may include gold (Au) or nickel (Ni), but are not limited to them. The metal nanoparticles are, for example, metal particles having a particle size that is nanometer order, specifically from several tens of nanometers to several hundreds of nanometers.

The sinter-bonding layer 3 may be formed by applying the above-mentioned sinter-bonding material 30 to the one surface 2a of the heat spreader 2, placing the semiconductor element 5 having the brush structure 4 on the sinter-bonding material 30, and sintering the sinter-bonding material 30 by heating without pressure. The sinter-bonding layer 3 is bonded to the heat spreader 2 and the brush structure 4, but is not directly bonded to the semiconductor element 5. In other words, the sinter-bonding layer 3 is disposed apart from a portion of the semiconductor element 5 different from the brush structure 4, and is bonded to tip ends of the brush structure 4. The sinter-bonding layer 3 has a thickness t in the extension direction D1 of metal wires 41 (described later). For example, the thickness t ranges from 10 μm to 500 μm.

The brush structure 4 includes the multiple metal wires 41 that are columnar and extend from the one surface 5a of the semiconductor element 5. In the brush structure 4, the tip ends of the multiple metal wires 41 are bonded to the sinter-bonding layer 3, and serve as a heat conductive path configured to transfer the heat from the semiconductor element 5 to the heat spreader 2.

For example, the multiple metal wires 41 are columnar wire bodies that are made of copper, silver, or other metal materials that have higher thermal conductivity than that of solder, and that can be electroplated. The multiple metal wires 41 are extended in a substantially straight line by electroplating. The term “substantially straight line” includes a state in which the metal wires 41 are formed in a linear shape along a normal direction to the one surface 5a of the semiconductor element 5. The term also includes a state in which the metal wires 41 are slightly inclined and can be regarded as being nearly linear, although the metal wires 41 are not exactly linear along the normal direction due to unavoidable factors in a manufacturing step. In other words, the multiple metal wires 41 are arranged such that an angle formed between the extension direction D1, in which the metal wires 41 are extended, and the one surface 5a is perpendicular or substantially perpendicular. Since the multiple metal wires 41 are bonded to the sinter-bonding layer 3 without pressure, the multiple metal wires 41 remain to be in the substantially straight line even after bonding.

The multiple metal wires 41 may be formed by forming a seed layer (not illustrated) on the one surface 5a of the semiconductor element 5, partially covering the seed layer with a patterned resist layer, and electroplating to grow metal wires from portions of the seed layer exposed from the resist layer. The above-mentioned resist layer (not illustrated) is removed after electroplating. The multiple metal wires 41 have a length in the extension direction D1, as a height h, which ranges from 5 μm to 500 μm.

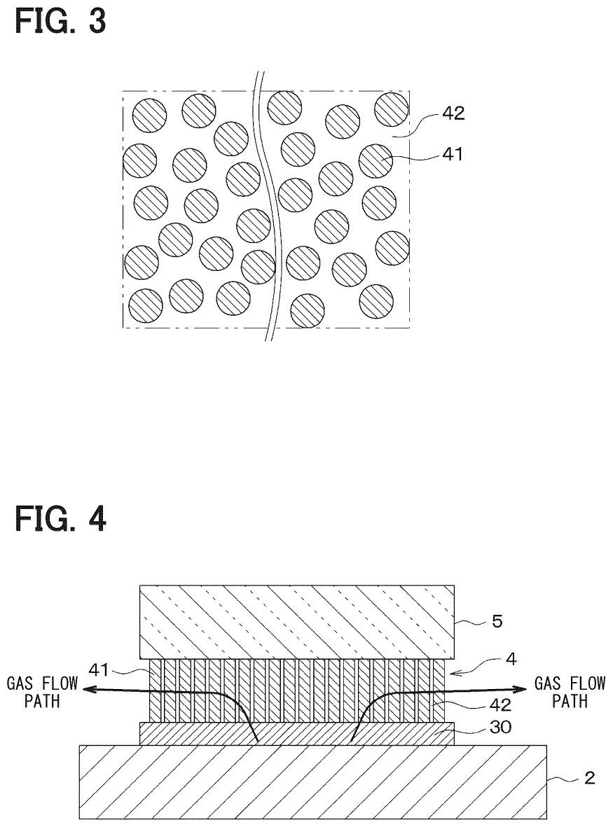

Here, as shown in FIG. 3, a plane perpendicular to the extension direction D1 of the metal wires 41 is referred to as a “perpendicular plane,” and empty spaces between the metal wires 41 in the perpendicular plane are referred to as “gap portions 42.” As shown in FIG. 4, the gap portions 42 serve as gas flow paths venting a gas generated from the sinter-bonding material 30 outward during a sintering process using the sinter-bonding material 30, and reducing generation of voids within the sinter-bonding layer 3.

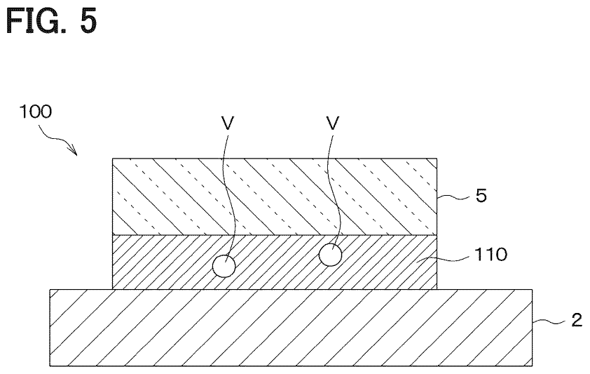

Furthermore, when porosity is defined as a proportion of an area occupied by the gap portions 42 in the brush structure 4, the porosity of the brush structure 4 ranges from 15% to 85%. When the porosity of the brush structure 4 is less than 15%, the gas generated from the sinter-bonding layer 3 cannot easily flow out, which makes it difficult to reduce the generation of voids in the sinter-bonding layer 3. For example, as a bonded structure 100 in a comparative example shown in FIG. 5, when the heat spreader 2 and the semiconductor element 5 are bonded together only via the sinter-bonding layer 110 without pressure, the gas generated from the sinter-bonding material cannot sufficiently flow out, resulting in generation of voids V in the sinter-bonding layer 110. When the porosity of the brush structure 4 is less than 15%, a phenomenon similar to that observed when only the sinter-bonding layer 110 is between the semiconductor element 5 and the heat spreader 2 (i.e., when the porosity is 0%) occurs. On the other hand, when the porosity of the brush structure 4 exceeds 85%, the heat dissipating path from the semiconductor element 5 to the heat spreader 2 decreases, resulting in reduction in thermal conductivity. In other words, the bonded structure 1, with the porosity of the brush structure 4 between 15% and 85%, inclusive, can ensure the thermal conductivity between the heat spreader 2 and the semiconductor element 5, and reduce the generation of voids in the sinter-bonding layer 3.

The porosity is a proportion of an area occupied by the gap portions 42 in the brush structure 4 when an outermost contour of the brush structure 4 in the perpendicular plane is regarded as a rectangular shape, as shown by a double dashed line in FIG. 3, and an area of this rectangular shape is defined as 100%. In addition, since the heat spreader 2 and the semiconductor element 5 are bonded together without pressure, the porosity of the brush structure 4 remains substantially the same before and after bonding with the sinter-bonding layer 3.

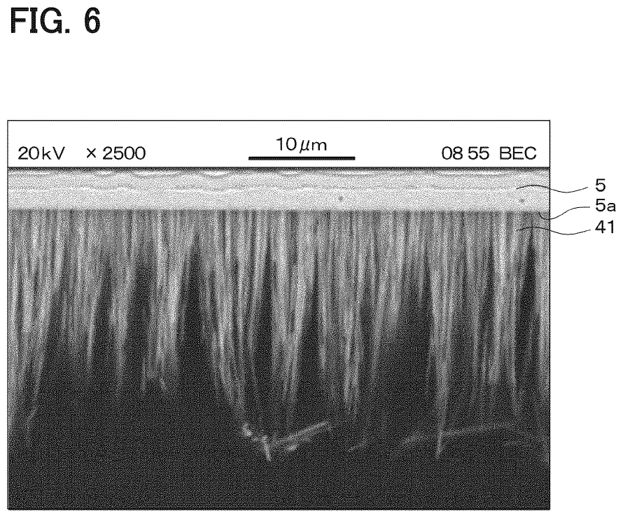

The semiconductor element 5 is, for example, formed in a plate shape having the one surface 5a, and is mainly made of a semiconductor material such as Si (silicon), SiC (silicon carbide), GaN (gallium nitride), GaO (gallium oxide), and diamond. The semiconductor element 5 is a power semiconductor element such as an IGBT or power MOSFET, and is manufactured by a known semiconductor process. IGBT and MOSFET are abbreviations for Insulated Gate Bipolar Transistor and Metal Oxide Semiconductor Field Effect Transistor, respectively. As shown in FIG. 6, for example, the semiconductor element 5 includes the multiple metal wires 41 with a length on the order of micrometers on the one surface 5a. FIG. 6 is a scanning electron microscope image showing a cross-sectional view of the semiconductor element 5 before bonding to the heat spreader 2.

The above describes the basic configuration of the bonded structure 1.

This description explains a case where the bonded structure 1 is adopted to a semiconductor device with a single-sided heat dissipating structure as a representative example. However, the disclosure is not limited to this. The bonded structure 1 may also be a semiconductor device with a double-sided heat dissipating structure, in which a heat dissipating member is bonded to a side opposite to the heat spreader 2 via the semiconductor element 5. Furthermore, the bonded structure 1 may have a structure in which the brush structure 4 is formed on one of the heat dissipating member as a first member and the heat generating member as a second member, and the sinter-bonding layer 3 is disposed on the other of the heat dissipating member and the heat generating member, and in which the sinter-bonding layer 3 and the tip ends of the brush structure 4 are bonded together. The bonded structure 1 may be adopted to configurations other than the semiconductor device, such as an electronic device in which the heat generating member is an electronic component other than a semiconductor element. Components other than a bonding structure defined by the sinter-bonding layer 3 and the brush structure 4 may be appropriately modified as needed.

### EXAMPLES

Next, evaluation results regarding the presence of voids in the sinter-bonding layer 3 and simulations of thermal conductivity will be described for working examples of the bonding structure, which have the sinter-bonding layer 3 and the brush structure 4 between the heat spreader 2 and the semiconductor element 5, and as well as for comparative examples with different configurations.

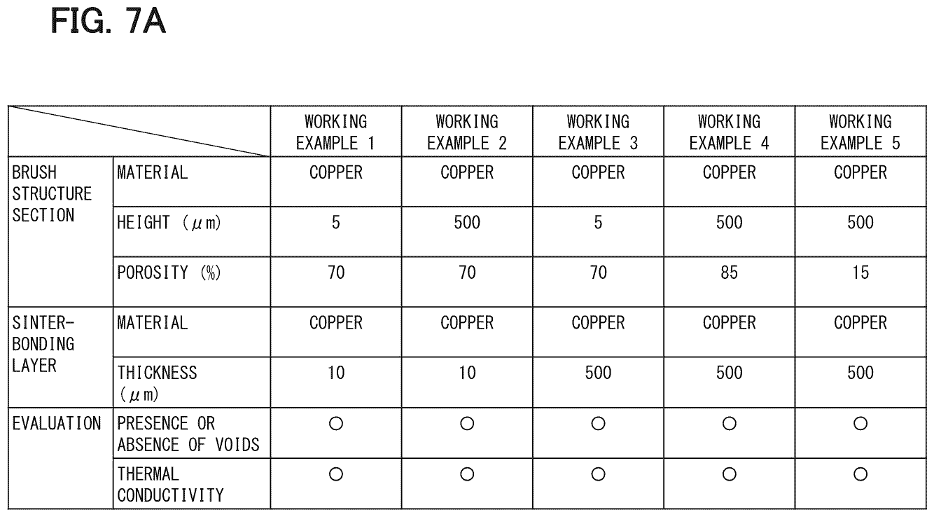

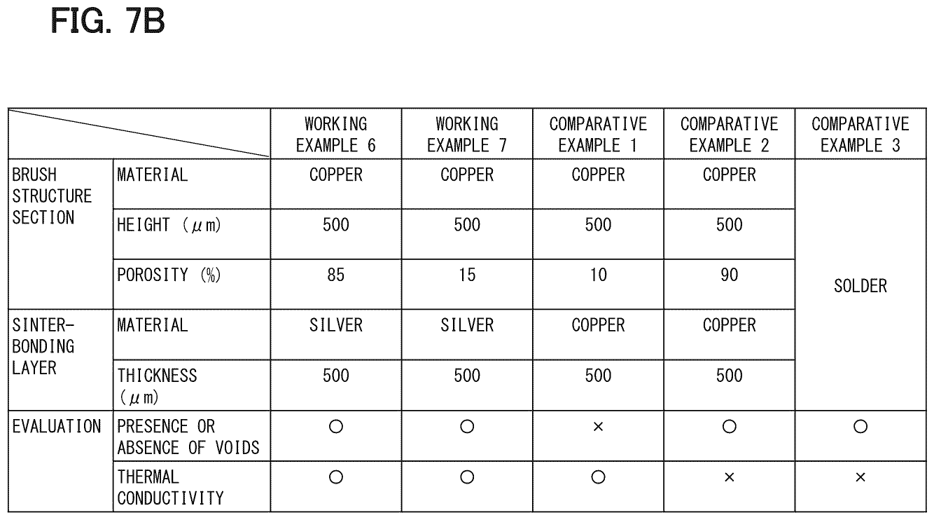

The simulation evaluation may be performed by using known numerical analysis software such as finite element method, or by using a thermal conduction calculation model for multilayer structures. The simulation evaluation results shown in FIGS. 7A and 7B are based on a premise in which the heat spreader 2 made of copper and the semiconductor element 5 made of SiC are bonded without pressure, and simulations are conducted by varying structural and material conditions of a bonded portion. In addition, the simulation evaluation in FIGS. 7A and 7B has been conducted by calculation using a theoretical formula of a parallel plate multilayer model.

The presence or absence of voids in FIGS. 7A and 7B is evaluated with “○” or “x”. When no voids are generated in the sinter-bonding layer 3 in the simulation evaluation, this case is indicated by “○”. When voids are generated in the sinter-bonding layer 3 in the simulation evaluation, this case is indicated by “x”. The thermal conductivity in FIGS. 7A and 7B is also evaluated with “○” or “x”. The bonding portion is defined as an entire structure between the heat spreader 2 and the semiconductor element 5, and when the thermal conductivity of the bonding portion is 60 W/mK or higher, this case is indicated by “○”. When the thermal conductivity of the bonding portion is less than 60 W/mK, this case is indicated by “x”.

Comparative examples 1 and 2, and working examples 1 to 5, include the sinter-bonding layer 3 and the brush structure 4 as the bonding portion, which are made of copper. Working examples 6 and 7 are different from the working examples 1 to 5 in that a material of the sinter-bonding layer 3 is silver.

In the working example 1 after bonding, a height of the metal wires 41 is 5 μm, the porosity of the brush structure 4 is 70%, and a thickness of the sinter-bonding layer 3 is 10 μm. In the working example 1, no voids generated in the sinter-bonding layer 3, and the overall thermal conductivity of the sinter-bonding layer 3 and the brush structure 4 was at 60 W/mK or higher.

In the working example 2 after bonding, the height of the metal wires 41 is 500 μm, the porosity of the brush structure 4 is 70%, and the thickness of the sinter-bonding layer 3 is 10 μm. In the working example 2, the generation of voids was reduced and the thermal conductivity of the bonding portion was ensured, similarly to the working example 1.

In the working example 3 after bonding, the height of the metal wires 41 is 5 μm, the porosity of the brush structure 4 is 70%, and the thickness of the sinter-bonding layer 3 is 500 μm. In the working example 3, the generation of voids was reduced and the thermal conductivity of the bonding portion was ensured, similarly to the working example 1.

In the working example 4 after bonding, the height of the metal wires 41 is 500 μm, the porosity of the brush structure 4 is 85%, and the thickness of the sinter-bonding layer 3 is 500 μm. In the working example 4, the generation of voids was reduced and the thermal conductivity of the bonding portion was ensured, similarly to the working example 1.

In the working example 5 after bonding, the height of the metal wires 41 is 500 μm, the porosity of the brush structure 4 is 15%, and the thickness of the sinter-bonding layer 3 is 500 μm. In the working example 5, the generation of voids was reduced and the thermal conductivity of the bonding portion was ensured, similarly to the working example 1.

The above evaluation results suggest that, when the sinter-bonding layer 3 and the metal wires 41 are made of copper, the porosity ranges from 15% to 85%, the thickness of the sinter-bonding layer 3 ranges from 10 μm to 500 μm, and the height of the metal wires 41 ranges from 5 μm to 500 μm, the generation of voids in the sinter-bonding layer 3 can be reduced. In this case, it is also possible to ensure the thermal conductivity between the heat spreader 2 and the semiconductor element 5, thereby achieving both void reduction in the sinter-bonding layer 3 and ensuring heat dissipating performance of the semiconductor element 5.

In the working example 6 after bonding, the height of the metal wires 41 is 500 μm, the porosity of the brush structure 4 is 85%, the thickness of the sinter-bonding layer 3 is 500 μm, and silver is used as a material of the sinter-bonding layer 3. In the working example 6, the generation of voids was reduced and the thermal conductivity of the bonding portion was ensured, similarly to the working example 1.

In the working example 7 after bonding, the height of the metal wires 41 is 500 μm, the porosity of the brush structure 4 is 15%, the thickness of the sinter-bonding layer 3 is 500 μm, and silver is used as the material of the sinter-bonding layer 3. In the working example 7, the generation of voids was reduced and the thermal conductivity of the bonding portion was ensured, similarly to the working example 1.

The evaluation results of the working examples 6 and 7 suggest that when the sinter-bonding layer 3 is made of silver, the height of the metal wires 41 and the thickness of the sinter-bonding layer 3 are 500 μm, and the porosity ranges from 15% to 85%, both the void reduction and ensuring of the thermal conductivity at the bonding portion can be achieved. Furthermore, in view of the evaluation results of the working examples 1 to 5, it is considered that, even when the sinter-bonding layer 3 is made of silver, both the void reduction and sufficient thermal conductivity at the bonding portion can be achieved as long as the height of the metal wires 41 is 5 μm or higher and the thickness of the sinter-bonding layer 3 is 10 μm or more.

On the other hand, in the comparative example 1 after bonding, the height of the metal wires 41 and the thickness of the sinter-bonding layer 3 are both 500 μm, and the porosity of the brush structure 4 is 10%. Although the comparative example 1 exhibited reliable thermal conductivity at the bonding portion, voids were generated in the sinter-bonding layer 3. According to this results, it is considered that, when the porosity of the brush structure 4 is 10% or less, the number of flow paths for gas generated from the sinter-bonding material is reduced, which makes it difficult for the gas to flow out, resulting in the generation of voids.

In the comparative example 2 after bonding, the height of the metal wires 41 and the thickness of the sinter-bonding layer 3 are both 500 μm, and the porosity of the brush structure 4 is 90%. In the comparative example 2, although the generation of voids in the sinter-bonding layer 3 was reduced, the thermal conductivity of the bonding was less than 60 K/mK. According to these results, it is considered that, when the porosity of the brush structure 4 is at least 90% or more, although it is possible to allow the gas generated from the sinter-bonding material to flow out, the number of metal wires 41 decreases, making it difficult to ensure the thermal conductivity at the bonding portion.

The comparative example 3 does not include the sinter-bonding layer 3 and the brush structure 4, and the heat spreader 2 and the semiconductor element 5 are bonded using solder. In the comparative example 3, although no voids were generated, the thermal conductivity is less than 60 K/mK, and it is impossible to achieve both void reduction and sufficient thermal conductivity at the bonding portion.

According to the above evaluation results, it is considered that, the bonded structure 1 having the sinter-bonding layer 3 and the brush structure 4 need to have the porosity in the brush structure 4 that ranges from 15% to 85%. Furthermore, in the bonded structure 1, the thickness of the sinter-bonding layer 3 may range from 10 μm to 500 μm, and the length of the metal wires 41 may range from 5 μm to 500. In addition, in the bonded structure 1, the sinter-bonding layer 3 and the metal wires 41 may be made of copper or silver. However, even if a metal material with higher thermal conductivity than that of solder is used, both the void reduction and ensuring the thermal conductivity at the bonding portion can be achieved.

According to the present embodiment, the bonded structure 1 includes the heat spreader 2 as the first member, the semiconductor element 5 that has the brush structure 4 as the second member, and the sinter-bonding layer 3 disposed separately from a portion of the second member different from the brush structure 4. The sinter-bonding layer 3 is bonded to the brush structure 4. The brush structure 4 is formed of the multiple columnar metal wires 41 and has the porosity ranging from 15% to 85%. Since the bonded structure 1 includes the brush structure 4 which has the porosity from 15% to 85% and is disposed on the sinter-bonding layer 3, the gas generated from the material of the sinter-bonding layer 3 during the sintering process can flow out through the gap portions 42 in the brush structure 4. Therefore, even if sintering is performed without pressure and an area of the bonding portion is large, a volatilization process for releasing the gas generated from the material of the sinter-bonding layer 3 to the outside is not required, resulting in the bonded structure 1 that can achieve both improved productivity and reduction of void generation. In addition, the bonded structure 1 has the following features.

(1) When a height is defined as a length along the extension direction D1 of the brush structure 4, the multiple metal wires 41 has the height that is 500 μm or less. Although it is considered that an effect of void reduction can be achieved even when the height of the metal wires 41 exceeds 500 μm, the height may be 500 μm or less in view of improving productivity and reducing manufacturing costs.

(2) The sinter-bonding layer 3 has a thickness along the extension direction D1 that is 500 μm or less.

(3) The multiple metal wires 41 are made of copper, silver, or other metal material having the higher thermal conductivity than solder.

(4) The sinter-bonding layer 3 is made of copper, silver, or other metal material having the higher thermal conductivity than solder.

### Other Embodiments

The present disclosure has been described in accordance with the embodiments. However, it is understood that the present disclosure is not limited to these embodiments or structures. The present disclosure also includes various modifications and equivalents. In addition, various combinations and forms, as well as other combinations and forms including only one, more, or fewer of these elements, are also within the scope and spirit of the present disclosure.

The constituent element(s) of each of the above embodiments is/are not necessarily essential unless it is specifically stated that the constituent element(s) is/are essential in the above embodiment, or unless the constituent element(s) is/are obviously essential in principle. Additionally, in the above embodiments, when the number, value, quantity, range, etc., of the elements of the embodiment are mentioned, they are not limited to those specific numbers unless explicitly stated as essential or clearly limited to specific numbers in principle. Furthermore, in each of the above embodiments, when referring to the shape, positional relationship, or the like of components, such shape or positional relationship is not limited thereto unless expressly indicated or inherently limited to a specific shape or positional relationship in principle.

While the present disclosure has been described with reference to embodiments thereof, it is to be understood that the disclosure is not limited to the embodiments and constructions. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. A bonded structure comprising:
a first member;
a second member having a brush structure formed of multiple metal wires, each of the multiple metal wires having a columnar shape; and
a sinter-bonding layer bonding the first member to the brush structure, and disposed apart from a portion of the second member that is different from the brush structure, wherein
the multiple metal wires extend in an extension direction,
porosity is defined as a proportion of an area occupied by gaps between the multiple metal wires in the brush structure in a plane perpendicular to the extension direction, and
the porosity of the brush structure falls within a range from 15% to 85%.

2. The bonded structure according to claim 1, wherein
the multiple metal wires have a height in the extension direction that is 500 μm or less.

3. The bonded structure according to claim 1, wherein
the sinter-bonding layer has a thickness in the extension direction that is 500 μm or less.

4. The bonded structure according to claim 1, wherein
the multiple metal wires are made of copper, silver, or a metal material having higher thermal conductivity than that of solder.

5. The bonded structure according to claim 1, wherein
the sinter-bonding layer is made of copper, silver, or a metal material having higher thermal conductivity than that of solder.
